(19) United States
(12) Patent Application Publication
(10) Pub. No.: US 2016/0322329 A1
(43) Pub. Date: Nov. 3, 2016

(54) WIRE BOND STRENGTHENING

(71) Applicant: SKYWORKS SOLUTIONS, INC., Woburn, MA (US)

(72) Inventors: Aldrin Quinones GARING, Mexicali (MX); Miguel CAMARGO SOTO, Mexicali (MX)

(21) Appl. No.: 15/083,045

(22) Filed: Mar. 28, 2016

Related U.S. Application Data
(60) Provisional application No. 62/149,915, filed on Apr. 20, 2015.

(51) Int. Cl. H01L 23/00; B23K 20/26; B23K 20/02; B23K 20/10; H01L 21/66; B23K 20/00

(52) U.S. Cl. CPC H01L 24/85; H01L 22/12; H01L 24/78; H01L 24/48; B23K 20/005; B23K 20/023; B23K 20/10; B23K 20/26; H01L 2224/85948; H01L 2224/78343; H01L 2224/78253; H01L 2224/85203; H01L 2224/85205; H01L 2224/48465; H01L 2224/48799

(57) ABSTRACT

Wire bond strengthening. A method of strengthening a wire bond can include lowering an unthreaded capillary of a wire bonder to a bond strengthening site associated with a bond site of a formed wire bond. The method can further include applying a compressive force between the capillary and the bond strengthening site for a period of time and applying at least one of heat or ultrasonic energy to the bond strengthening site for the period of time. The method can include raising the capillary from the bond strengthening site.

### CROSS-REFERENCE TO RELATED APPLICATION(S)

This application claims priority to U.S. Provisional Application No. 62/149,915 filed Apr. 20, 2015, entitled WIRE BOND STRENGTHENING, the disclosure of which is hereby expressly incorporated by reference herein in its entirety.

### BACKGROUND

1. Field

The present disclosure generally relates to wire bonds.

2. Description of the Related Art

During semiconductor device fabrication, wire bonding may be used to connect integrated circuits or other semiconductor devices to a substrate to form a semiconductor package. When wire bonding a semiconductor device to a substrate, various circumstances may influence the strength of the resulting wire bond. For example, contamination of integrated circuit leads, low printed circuit board quality, poor bonding parameter selection, or other issues may result in a weak bond. In some cases, when a weak bond is detected on a package, an entire lot of packages to which the package belongs may be disposed of as scrap.

### SUMMARY

In accordance with some implementations, the present disclosure relates to a method of strengthening a bond. The method includes lowering an unthreaded capillary of a wire bonder to a bond strengthening site associated with a bond site of a formed wire bond. The method further includes applying a compressive force between the capillary and the bond strengthening site for a period of time and applying at least one of heat or ultrasonic energy to the bond strengthening site for the period of time. The method further includes raising the capillary from the bond strengthening site.

In some embodiments, the wire bond can be a copper wire bond. In some embodiments, the wire bond can be a stitch bond.

In some embodiments, the bond strengthening site can be the bond site. In some embodiments, the bond strengthening site can be a site proximal to the bond site. In some embodiments, the bond site can be disposed between the bond strengthening site and a wire of the wire bond. In some embodiments, the bond site can be between approximately 10 and 40 micrometers from the bond site.

In some embodiments, lowering the unthreaded capillary of the wire bonder can include retracting a wire of the wire bonder.

In some embodiments, applying at least one of heat or ultrasonic energy to the bond strengthening site can include heating the bond strengthening site to between approximately 100 and 300 degrees centigrade. In some embodiments, applying at least one of heat or ultrasonic energy to the bond strengthening site can include applying approximately a 60 kilohertz (kHz) or 120 kHz ultrasonic acoustic wave. In some embodiments, the ultrasonic acoustic wave can move the capillary in a scrubbing motion at the bond strengthening site.

In some embodiments, the method can further include receiving a set of bond strengthening parameters via a user interface. In some embodiments, applying the compressive force and applying the at least one of heat or ultrasonic energy can be performed according to the set of bond strengthening parameters.

In some implementations, the present disclosure relates to a method of recovering at least a portion of a lot of packages. The method includes forming a bond on each of a lot of packages and performing a wire pull test of the bond of a first package of the lot of packages. The method further includes, responsive to determining that the wire pull test was failed, strengthening the bond of a second package of the lot of packages according to a set of bond strengthening parameters without introducing additional material to the bond of the second package.

In some embodiments, the bond of each of the lot of packages can be a copper wire stitch bond.

In some embodiments, strengthening the bond of the second package can include applying a compressive force and at least one of heat or ultrasonic energy to the bond.

In some embodiments, the method can further include receiving the set of bond strengthening parameters via a user interface.

In some embodiments, the method can further include performing a wire pull test of the bond of a second package of the lot of packages. In some embodiments, the method can further include, responsive to determining that the wire pull test of the bond of the second package was failed, strengthening the bond of another second package of the lot of packages according to a different set of bond strengthening parameters. In some embodiments, the method can further include, responsive to determining that the wire pull test of the bond of the second package was passed, strengthening the bond of each of set of third packages of the lot of packages according the set of bond strengthening parameters.

In some embodiments, the method can further include determining whether a wire pull test of the bond of each of the set of third packages produced more than a threshold amount of variation. In some embodiments, the method can further include, responsive to determining that the wire pull test of the bond of each of the set of third packages did not produce more than a threshold amount of variation, strengthening the bond of the remaining packages of the lot according to the set of bond strengthening parameters.

In some implementations, the present disclosure relates to a wire bonding system. The wire bonding system including a wire bonder including a capillary. The wire bonding system further includes a processing module coupled to the wire bonder and configured to control the wire bonder to lower the capillary in an unthreaded state to a bond strengthening site associated with a bond site of a formed wire bond, apply a compressive force between the capillary and the bond strengthening site for a period of time, apply at least one of heat or ultrasonic energy to the bond strengthening site for the period of time, and raise the capillary from the bond strengthening site.

In some embodiments, the wire bonding system can further include a user interface configured to receive a set of bond strengthening parameters. In some embodiments, the processing module can be configured to control the wire bonder to apply the compressive force and apply the at least one of heat or ultrasonic energy according to the set of bond strengthening parameters.

In some embodiments, the processing module can be configured to control the wire bonder to retract a wire to place the capillary in the unthreaded state.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows an example of a wire bonding configuration that includes a package being formed by a wire bonding system.

FIG. 2 shows an example of a wire bonding configuration including a wire bonding system configured to form wire bonds of a package.

FIG. 3 shows a flowchart representation of a method of forming a wire bond in accordance with some implementations.

FIG. 4A shows a cross-section of a capillary threaded with wire.

FIG. 4B shows a cross-section of a capillary having a ball formed by melting the tip of a wire.

FIG. 4C shows a cross-section of a capillary lowered to a first bond site and being used to form a ball bond at the first bond site.

FIG. 4D shows a cross-section of a capillary looped from a first bond site to a second bond site and being used to form a stitch bond at the second bond site.

FIG. 4E shows a cross-section of a capillary raised from a second bond site.

FIG. 5 shows a flowchart representation of a method of strengthening a bond in accordance with some implementations.

FIG. 6 shows a cross-section of an unthreaded capillary lowered to a bond strengthening site associated with a bond site of a formed bond of a package.

FIG. 7 shows a flowchart representation of a method of recovering at least a portion of a lot of packages in accordance with some implementations.

FIG. 8 depicts a module having one or more features as described herein.

FIG. 9 depicts a wireless device having one or more features described herein.

### DETAILED DESCRIPTION OF SOME EMBODIMENTS

The headings provided herein, if any, are for convenience only and do not necessarily affect the scope or meaning of the claimed invention.

As described above, wire bonding may be used to connect semiconductor devices to a substrate to form a semiconductor package. When wire bonding a semiconductor device to a substrate, various circumstances may influence the strength of the resulting wire bond. In some cases, when a weak bond is detected on a package, an entire lot of packages to which the package belongs may be disposed of as scrap.

Disclosed herein are various examples of circuits, devices and methods that can be configured to, among others, address the foregoing challenges associated with wire bonding. In some implementations as described herein, rather than scrap an entire lot of packages when a weak bond is detected on one of the packages, wire bonds of the lot are strengthened and at least a portion of the lot may be recovered.

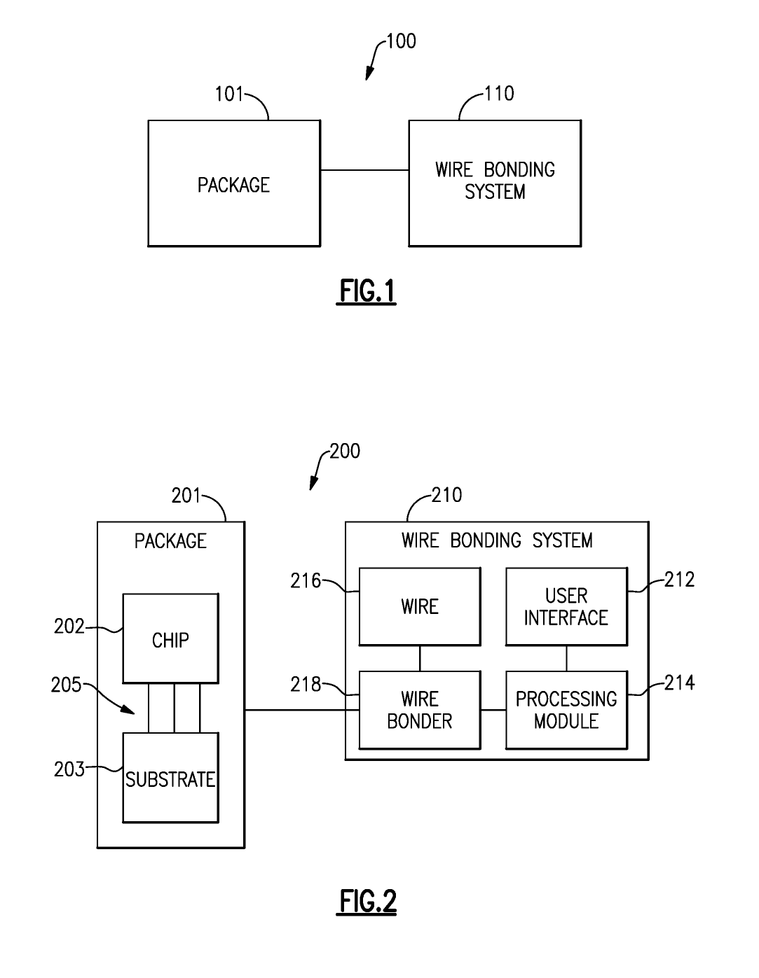

FIG. 1 shows an example of a wire bonding configuration 100 that includes a package 101 being formed by a wire bonding system 110. The wire bonding system 110 forms one or more wire bonds between components of the package 101. The wire bonding system 110 may form wire bonds for multiple packages, such as a strip of packages or a lot of packages (which may include multiple strips). The wire bonding system 110, as described further below, may, after forming one or more wire bonds, strengthen the bonds through further processing.

FIG. 2 shows an example of a wire bonding configuration 200 including a wire bonding system 210 configured to form wire bonds 205 of a package 201. The package 201 includes a chip 202 and a substrate 203. The chip 202 may be an integrated circuit or other semiconductor device. The chip 202 may be, for example, a radio-frequency (RF) module to be used in a wireless communication device to transmit and receive wireless communication signals. The substrate 203 may be, for example, a printed circuit board (PCB).

The wire bonding system 210 includes a processing module 214 that controls a wire bonder 218 to form one or more wire bonds 205 between the chip 202 and the substrate 203. To control the wire bonder 218, the processing module 214 may transmit command signals to the wire bonder 218 to activate various components of the wire bonder 218, such as motors and heaters, as described below. The processing module 214 may be configured to provide a user interface 212 to receive information from a user and provide information to a user. The user interface 212 may include one or more input devices (such as a keyboard) and one or more output devices (such as a display). The processing module 214 may receive, via the user interface 212, parameters to be applied during the wire bonding process.

The wire bonding system 210 includes wire 216 used by the wire bonder 218 to form the wire bonds 205. The wire 216 may be, for example, copper wire with a wire diameter of approximately 17 micrometers (microns) or greater. In some implementations, the wire 216 is gold wire, aluminum wire, silver wire, or made of any other material. In some implementations, the wire 216 has a wire diameter between approximately 15 micrometers and 300 micrometers.

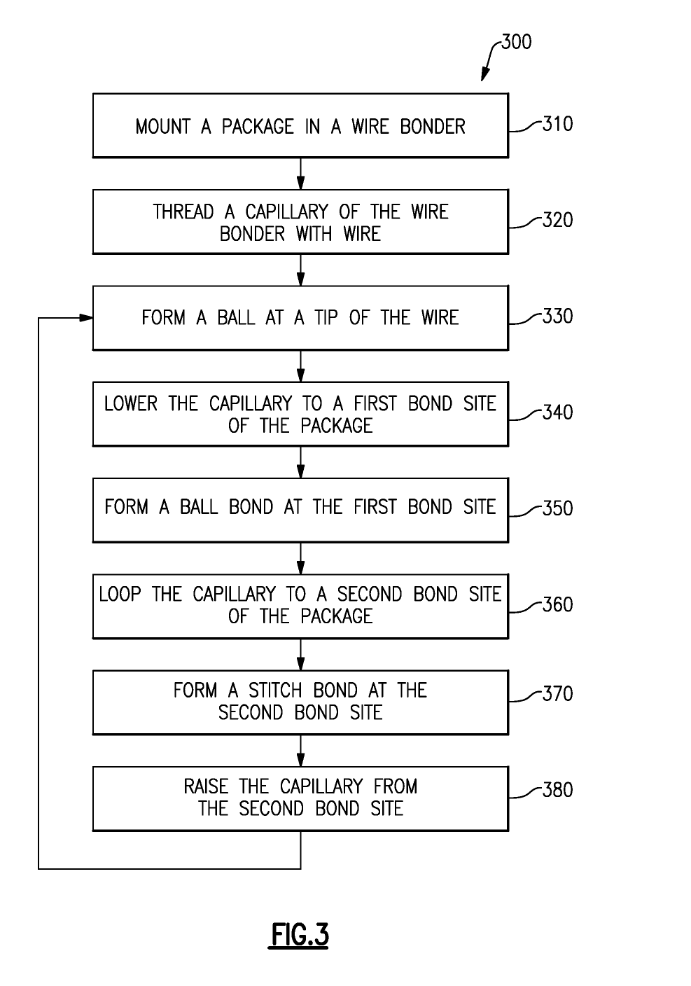

FIG. 3 shows a flowchart representation of a method 300 of forming a wire bond in accordance with some implementations. In some implementations (and as detailed below as an example), the method 300 is at least partially performed by a wire bonding system, such as the wire bonding system 210 of FIG. 2. In some implementations, the method 300 is at least partially performed by processing logic (such as the processing module 214 of FIG. 2), including hardware, firmware, software, or a combination thereof. In some implementations, the method 300 is at least partially performed by a processor executing code stored in a non-transitory computer-readable medium (e.g., a memory).

The method 300 begins, at block 310, with the mounting of a package in a wire bonder. Mounting the package may include placing the package between a window clamp and a heater block and clamping the package, using the window clamp, to the wire bonder. The window clamp may be a metal piece that exposes a top side of the package (where the bonds are to be formed) and secures the package with respect to the wire bonder. The heater block may be a metal piece that conducts heat from the wire bonder to the package during the wire bonding process. The heater block may, for example, heat the package to between approximately 100 degrees and 300 degrees centigrade.

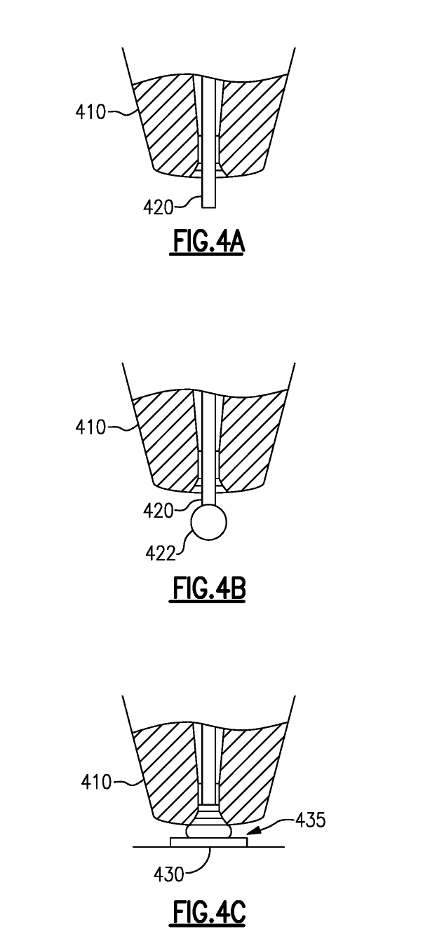

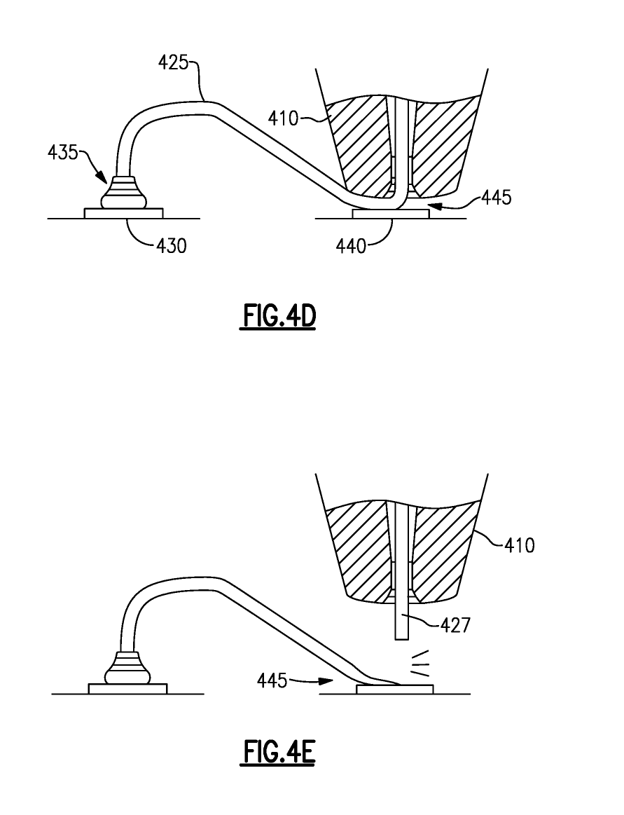

At block 320, a capillary of the wire bonder is threaded with wire. FIG. 4A shows a cross-section of a capillary 410 threaded with wire 420. In some implementations, the capillary 410 is a disposable piece having radial symmetry through which the wire is threaded. The capillary 410 may include glass, tungsten carbide, ceramic, metal, or any other material. The wire 420 may be, for example, copper wire. The wire 420 may have a wire diameter of approximately 17 micrometers or greater. In some implementations, as described above, the wire 420 may be formed of other materials or have other wire diameters.

Returning to FIG. 3, at block 330, a ball is formed at a tip of the wire. FIG. 4B shows a cross-section of a capillary 410 having a ball 422 formed by melting the tip of a wire 420. The ball 422 may be formed by ionization of the air gap between the wire 420 and the package in a process called “electronic flame-off” (EFO). The resulting ball may be known as a “free air ball” (FAB). The ball 422 may be formed by other methods.

Returning to FIG. 3, at block 340, the capillary is lowered to a first bond site of the package. The first bond site may be, for example, a lead of a chip. The capillary may be lowered to the first bond site by a motor of a wire bonder controlled by a processing module. Lowering the capillary to the first bond site may include moving the capillary to a position above the first bond site (e.g., from another bond site) and lowering the capillary. Lowering the capillary to the first bond site may include activating wire clamps of the capillary that fix the position of the wire within the capillary. At block 350, the wire bonding system forms a ball bond at the first bond site. FIG. 4C shows a cross-section of a capillary 410 lowered to a first bond site 430 and being used to form a ball bond 435 at the first bond site 430.

The ball bond 435 may be formed by applying a compressive force between the capillary 410 and the first bond site 430 for a period of time. The ball bond 435 may be formed by further applying heat and/or ultrasonic energy (USG) while applying the compressive force. The heat may be applied by the wire bonding system via the heater block as described above or via heaters within the capillary 410. The heat applied may increase the temperature at the bond site to between 100 and 300 degrees centigrade. For example, the bond site may be heated to approximately 190 degrees or approximately 200 degrees centigrade. The ultrasonic energy may be acoustic energy (e.g., sound waves) of approximately 60 kHz or 120 kHz that moves the capillary in a scrubbing motion at the first bond site 430.

Bonding parameters used by the wire bonding system may include the period of time, the compressive force, the temperature of the bond site, the USG frequency, the strength of the USG, and other parameters. The bonding parameters may be set via a user interface (e.g., the user interface 212 of FIG. 2). Accordingly, forming the ball bond (at block 350 of FIG. 3) may include forming the ball bond according to a set of bonding parameters.

At block 360, the wire bonding system loops the capillary to a second bond site of the package. At block 370, the wire bonding system forms a stich bond at the second bond site. FIG. 4D shows a cross-section of a capillary 410 looped from a first bond site 430 to a second bond site 440 and being used to form a stitch bond 445 at the second bond site 440.

The second bond site 440 may be, for example, pad of a PCB. The capillary 410 may be looped to the second bond site 440 by a motor of a wire bonder controlled by a processing module. Looping the capillary 410 to the second bond site 440 (e.g., as in block 360 of FIG. 3) may include deactivating wire clamps of the capillary, raising the capillary to a loop height above the first bond site 430, moving the capillary 410 to a position above the second bond site 440, activating the wire clamps, and lowering the capillary 410 to the second bond site 440. Looping the capillary to the second bond site 440 (e.g., as in block 360 of FIG. 3) may, thus, form a loop 425 of wire between the first bond site 430 and the second bond site 440. The shape of the loop 425 may be referred to as a loop profile.

The stich bond 445 may be formed by applying a compressive force between the capillary 410 and the second bond site 440 for a period of time. The stitch bond 445 may be formed by further applying heat and/or ultrasonic energy (USG) while applying the compressive force. The heat may be applied by the wire bonding system via the heater block as described above or via heaters within the capillary 410. The heat applied may increase the temperature at the bond site to between approximately 100 and 300 degrees centigrade. For example, the bond site may be heated to approximately 190 degrees centigrade or 200 degrees centigrade. The ultrasonic energy may be acoustic energy (e.g., sound waves) of approximately 60 kHz or 120 kHz that moves the capillary in a scrubbing motion at the second bond site 440.

As noted above, bonding parameters used by the wire bonding system may include the period of time, the compressive force, the temperature of the bond site, the USG frequency, the strength of the USG, and other parameters. The bonding parameters may be set via a user interface (e.g., the user interface 212 of FIG. 2). Accordingly, forming the stitch bond (at block 370 of FIG. 3) may include forming the stitch bond according to a set of bonding parameters.

At block 380, the wire bonding system raises the capillary from the second bond site. FIG. 4E shows a cross-section of a capillary 410 raised from a second bond site 440. The capillary 410 may be raised from the second bond site 440 by a motor of a wire bonder controlled by a processing module. Raising the capillary 410 from the second bond site 440 may include deactivating wire clamps of the capillary, raising the capillary a first distance from the second bond site, activating the wire clamps, and raising the capillary a second distance from the second bond site. With the wire clamps deactivated, raising the capillary 410 the first distance from the second bond site 440 may produce a length of wire 427 protruding from the capillary. With the wire clamps activated, raising the capillary 410 the second distance from the second site 440 may break the wire at the stitch bond 445.

In some implementations, the wire bonding system forms a security bond on the stitch bond 445. To form the security bond, the wire bonding system forms a ball at the tip of the wire, lowers the capillary 410 to the stitch bond 445 and applies a compressive force between the capillary 410 and the second bond site 440 for a period of time. The security bond 445 may be formed by further applying one or more of heat and/or ultrasonic energy (USG) while applying the compressive force. Accordingly, forming the security bond may include forming the security bond according to a set of bonding parameters.

In some implementations, forming the security bond may increase the strength of the stitch bond 440. However, in some implementations, the security bond may decrease the strength of the stitch bond 440. For example, when forming copper wire bonds, a security bond may be unstable and likely to result in a decrease in the strength of the stich bond. Thus, in some implementations, the wire bonding system does not form a security bond on the stitch bond 445.

The method 300 returns to block 330 where the wire bonding system forms a ball at the tip of the length of wire 427 and repeats to produce a number of wire bonds connecting components of the package as described above.

The strength of a bond may be tested (by the wire bonding system or a separate bond testing system) using a number of different bond strength tests. In some implementations, the strength of a bond is tested with a wire pull test by which a wire is pulled upward (perpendicular to the chip or substrate) by a hook. The wire pull test may be a “destructive” test that produces an indication of the amount of force required to break the bond or the wire. A bond may fail a destructive wire pull test if the amount of force required to break the bond or the wire is below a threshold. Similarly, the bond may pass a destructive wire pull test if the amount of force required to break the bond or the wire is above a threshold. The wire pull test may be a “non-destructive” test that produces an indication of whether a threshold amount of force may be applied without breaking the bond or the wire. A bond may fail a non-destructive wire pull test if application of the threshold amount of force breaks the bond or the wire. Similarly, a bond may pass a non-destructive wire pull test if application of the threshold amount of force does not break the bond or the wire. In some implementations, the strength of a bond is tested with a shear test by which a force is applied to the bond in a lateral direction (parallel to the chip or substrate). The shear test may be a destructive or a non-destructive test.

After forming one or more bonds for each package of a lot, a wire bonding system may perform one or more bond strength tests for one or more bonds of a subset of the packages (e.g., one or more of the packages). In some implementations, if one or more of the bonds fails a bond strength test, the lot may be scrapped and not implemented in finished user devices that may be sold to customers. However, in some implementations, if one or more of the bonds fails a bond strength test, other bonds of the lot may be strengthened and, ultimately, implemented in finished user devices that may be sold to customers.

FIG. 5 shows a flowchart representation of a method 500 of strengthening a bond in accordance with some implementations. In some implementations (and as detailed below as an example), the method 500 is at least partially performed by a wire bonding system, such as the wire bonding system 210 of FIG. 2. In some implementations, the method 500 is at least partially performed by processing logic (such as the processing module 214 of FIG. 2), including hardware, firmware, software, or a combination thereof. In some implementations, the method 500 is at least partially performed by a processor executing code stored in a non-transitory computer-readable medium (e.g., a memory).

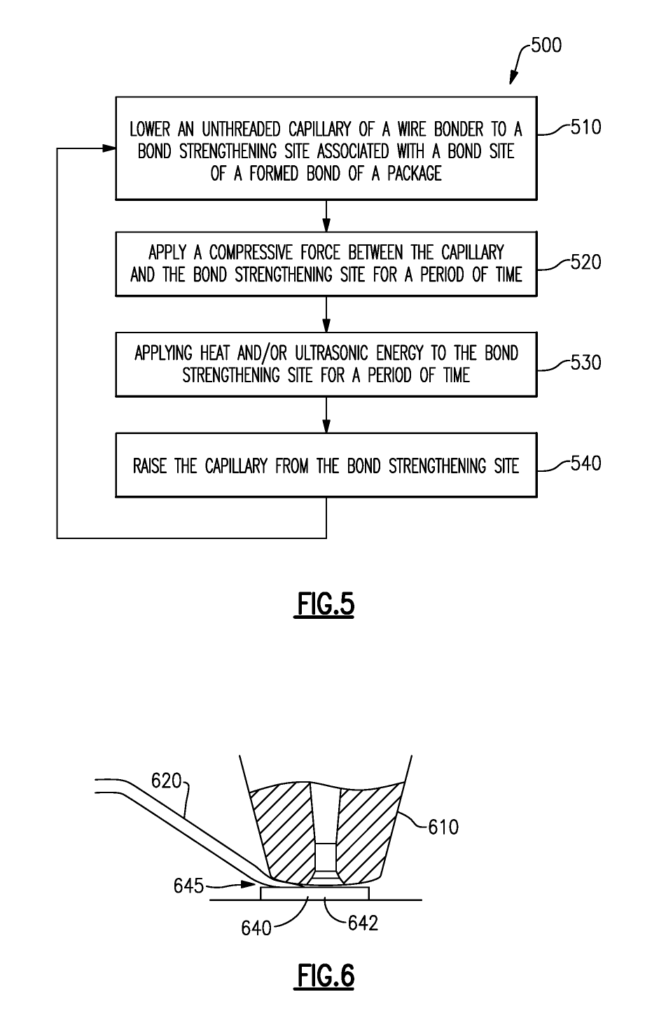

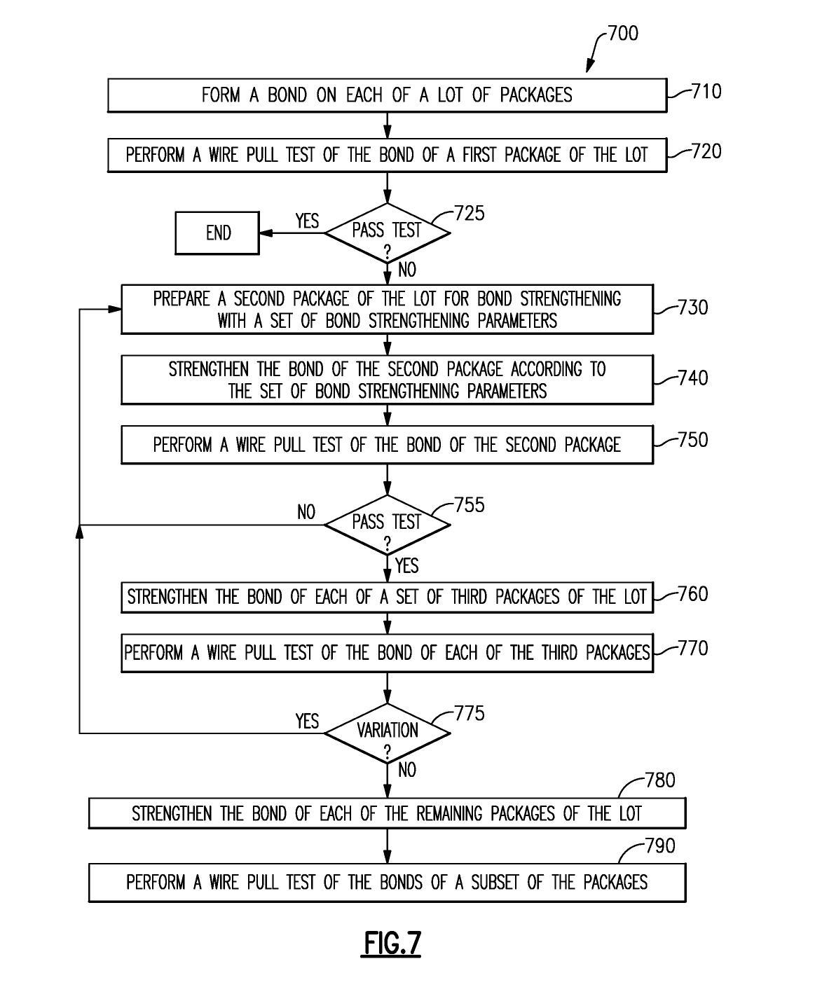

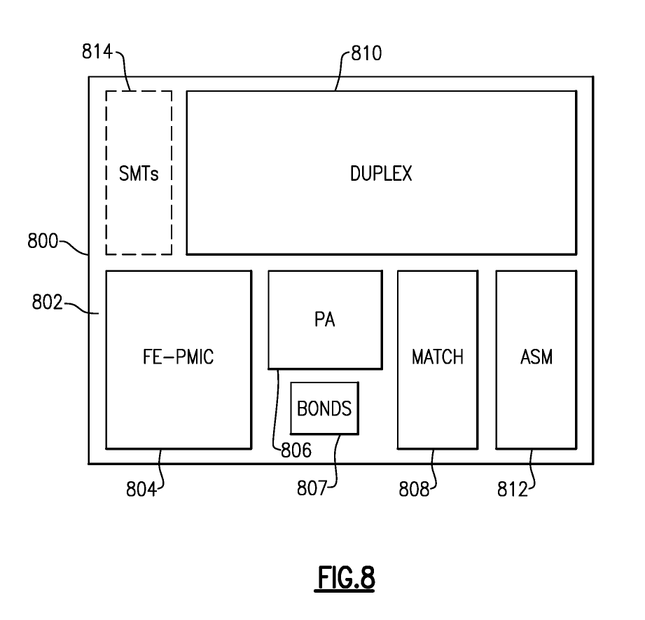

The method 500 begins, at block 510, with the lowering of an unthreaded capillary of a wire bonder to a bond strengthening site associated with a bond site of a formed bond of a package. FIG. 6 shows a cross-section of an unthreaded capillary 610 lowered to a bond strengthening site 642 associated with a bond site 640 of a formed bond 645 of a package.

The capillary 610 may be lowered to the bond strengthening site 642 by a motor controlled by a processing module. Lowering the capillary 610 to the bond strengthening site 642 may include moving the capillary 610 to a position above the bond strengthening site 642 (e.g., from another site). The bond strengthening site 642 may be the bond site 640 or another site proximal to the bond site 640 (as shown in FIG. 6). For example, the bond strengthening site 642 may be a site further from the bond wire 620 than the bond site 640 to avoid any damage to the bond wire 620 or wire sweeping. Thus, in some implementations, the bond site 640 is disposed between the bond strengthening site 642 and the bond wire 620. In some implementations, the bond strengthening site 642 is the bond site 640 except for critical wires or those with particular loop profile requirements, in which case the bond strengthening site 642 is disposed proximal to the bond site 640 (e.g., slightly away from the bond wire 620). As an example, the bond strengthening site 642 may be between 0 and 2 wire diameters from the bond site 640. In particular, the bond strengthening site 642 may be between 0.25 and 1.25 wire diameters from the bond site 642. As another example, the bond strengthening site 642 may be between approximately 0 and 100 micrometers from the bond site 640. In particular, the bond strengthening site 642 may be between approximately 10 and 40 micrometers from the bond site 640.

As noted above, the wire bonding system lowers the capillary 610 in an unthreaded state to the bond strengthening site 642. To that end, the wire bonding system may retract a bonding wire or otherwise remove the bonding wire from the capillary 610 to place the capillary 610 in the unthreaded state. The unthreaded capillary 610 may include bonding wire partially disposed within the capillary 610 but not exposed at the tip of the capillary 640. Thus, bond 645 is strengthened without additional wire or other additional material. Further, the bond 645 is strengthened without the use of forming gas (e.g., nitrogen or another inert gas) that may be used during the formation of a free air ball.

The bond 645 may be a stich bond (as illustrated in FIG. 6). In some implementations, the bond 645 is a ball bond, a wedge bond, or another type of bond.

Returning to FIG. 5, at block 520, the wire bonding system applies a compressive force between the capillary 610 and the bond strengthening site 642 for a period of time. At block 530, the wire bonding system applies at least one of heat or ultrasonic energy to the site strengthening site for the period of time. The heat may be applied by the wire bonding system via a heater block or via heaters within the capillary 610. The heat applied may increase the temperature at the bond site to between approximately 100 and 300 degrees centigrade. For example, the bond site may be heated to approximately 190 degrees centigrade or 200 degrees centigrade. The ultrasonic energy may be acoustic energy (e.g., sound waves) of approximately 60 kHz or 120 kHz that moves the capillary 610 in a scrubbing motion at the bond strengthening site 642.

Bonding strengthening parameters used by the wire bonding system may include the period of time, the compressive force, the temperature of the bond site, the USG frequency, the strength of the USG, and other parameters. The bonding strengthening parameters may be set via a user interface (e.g., the user interface 212 of FIG. 2). Accordingly, applying the compressive force and at least one of heat or ultrasonic energy (at blocks 520 and 530 of FIG. 5) may include applying the compressive force and at least one of heat or ultrasonic energy according to a set of bonding strengthening parameters.

At block 540, the wire bonding system raises the capillary 610 from the bond strengthening site 642. The capillary 610 may be raised from the bond strengthening site 640 by a motor controlled by a processing module. From block 540, the method 500 may return to block 510 to strengthen one or more additional bonds.

Bonds strengthened with the method 500 may be more reliable and durable than those formed without the method 500. In particular, bonds strengthened with the method 500 may produce a larger indication of the amount of force required to break the bond or the wire when subjected to a wire pull test. Further, a set of bonds strengthened with the method 500 may produce indications with less variation when subjected to a wire pull test. In one implementation, bonds strengthened with the method 500 may have an average pull test of 9 grams with 1.3 sigma in variation. In some implementations, bonds strengthened with the method 500 are larger than those formed without the method 500. For example, the length and/or width of the bond after performing the method 500 may be approximately 2 to 5 times the wire diameter.

The method 500 of strengthening a bond may be used as part of a method of recovering at least a portion of lot that would otherwise be scrapped. An example of such a method is described below with respect to FIG. 7.

FIG. 7 shows a flowchart representation of a method 700 of recovering at least a portion of a lot of packages in accordance with some implementations. In some implementations (and as detailed below as an example), the method 700 is at least partially performed by a wire bonding system, such as the wire bonding system 210 of FIG. 2. In some implementations, the method 700 is at least partially performed by processing logic (such as the processing module 214 of FIG. 2), including hardware, firmware, software, or a combination thereof. In some implementations, the method 700 is at least partially performed by a processor executing code stored in a non-transitory computer-readable medium (e.g., a memory).

The method 700 begins, at block 710, with the wire bonding system forming a bond on each of a lot of packages. The wire bonding system may form the bond as described above with respect to FIG. 3. The bond may be a ball bond, a stich bond, a wedge bond, or any other type of bond. Forming a bond on each of a lot of packages may include forming more than one bond on each of the lot of packages. Similarly, testing a bond of a package and strengthening a bond of package as described below may include testing or strengthening multiple bonds of package. For simplicity of explanation only, however, the method 700 is described for one bond of each package.

At block 720, the wire bonding system performs a wire pull test of the bond of a first package of the lot. In some implementations, another bond strengthening test (e.g., a shear test) may be substituted for or added to the wire pull test (in block 720 and/or other blocks). In some implementations, the wire bonding system performs a wire pull test of the bond (or bonds) of multiple packages of the lot.

At block 725, the wire bonding system determines whether the wire pull test was passed or failed. The wire pull test may be passed if the amount of force required to break the bond or wire is above a threshold. If the wire pull test is passed, the method 700 ends and the lot (possibly excluding the first package) may be implemented in finished user devices that may be sold to customers. If the wire pull test is failed, rather than scrapping the lot, the method 700 proceeds to block 730.

At block 730, the wire bonding system prepares a second package of the lot for bond strengthening. Preparing the second package for bond strengthening may include mounting the second package in a wire bonder. Mounting the second package may include placing the second package between a window clamp and a heater block and clamping the package, using the window clamp, to the wire bonder. Preparing the second package for bond strengthening may include replacing a capillary of the wire bonder, particularly if the capillary is damaged. Preparing the second package for bond strengthening may include retracting (or otherwise removing) a wire from a capillary to produce an unthreaded capillary for bond strengthening. Preparing the second package for bond strengthening may include perform a wire bonder calibration, including an ultrasonic energy calibration and/or a capillary centering calibration.

Preparing the second package for bond strengthening may include determining a set of bond strengthening parameters. The bond strengthening parameters may include, as described above, a period of time, a compressive force, a temperature of the bond strengthening site, a USG frequency, a strength of USG, and other parameters. In some implementations, the bond strengthening parameters are set via a user interface (e.g., the user interface 212 of FIG. 2). Thus, in some implementations, preparing the second package for bond strengthening includes receiving a set of bond strengthening parameters. In some implementations, the bond strengthening parameters are determined by the wire bonding system without receiving them via a user interface.

At block 740, the wire bonding system strengthens the bond of the second package according to the set of bond strengthening parameters. The wire bonding system may strengthen the bond as described above with respect to FIG. 5. Thus, in some implementations, the wire bonding system strengthens the bond of the second package without introducing additional material to the bond.

At block 750, the wire bonding system performs a wire pull test of the bond the second package. At block 755, the wire bonding system determines whether the wire pull test was passed or failed. The wire pull test may be passed if the amount of force required to break the bond or wire is above a threshold. If the wire pull test is failed, the method 700 returns to block 730 where another second package is prepared for bond strengthening with a different set of bond strengthening parameters. The bond strengthening parameters may be changed by one or more of increasing or decreasing the period of time, increasing or decreasing the compressive force, increasing or decreasing the temperature of the bond strengthening site, increasing or decreasing the USG frequency, increasing or decreasing the strength of USG, or changing other parameters. For example, the bond strengthening parameters may include a tool inflection point (TIP) indicative of distance from the bond at which the capillary reaches a relatively constant descent velocity or a contact velocity (CV) indicative of the velocity of the capillary when it contacts the bond.

The bond strengthening parameters may be changed based on a size of the stitch, a shape of the stich, and the amount of force required to break the bond or wire. For example, if the size of the stich is less than twice the diameter of the wire, the CV may be increased (e.g., by 0.05 mils/millisecond), or the compressive force may be increased (e.g., by 10 grams). As another example, if the size of the stich is greater than five times the diameter of the wire, the CV may be reduced (e.g., by 0.05 mils/millisecond), or the compressive force may be reduced (e.g., by 10 grams). As another example, to increase the amount of force required to break the bond or wire, or in response to the shape of the stitch being non-uniform, the USG strength may be increased (e.g., by 10 milliamps) or the period of time may be increased (e.g., by 5 milliseconds). Other bond strengthening parameters may be changed in response to other characteristics of the stitch.

If the wire pull test is passed (at block 755), the method 700 proceeds to block 760 where the wire bonding system strengthens the bond of each of a set of third packages of the lot according to the set of bonding parameters that were used to successfully strengthen the bond of the second package. The set of third packages may be a strip of packages of the lot.

At block 770, the wire bonding system performs a wire pull test of the bond of each of the third packages. At block 775, the wire bonding system determines whether the wire pull test produced more than a threshold amount of variation. Because the wire pull test was passed for the second package having its bond strengthened according the set of bond strengthening parameters, each of the third packages is likely to pass the wire pull test. However, too much variation in the wire pull test may be undesirable. Thus, if the wire bonding system determines that the wire pull test produced more than a threshold amount of variation, the method 700 returns to block 730 where another second package is prepared for bond strengthening with a different set of bond strengthening parameters.

If the wire pull produces less than a threshold amount of variation (at block 775), the method 700 proceeds to block 780 where the wire bonding system strengthens the bond of each of the remaining packages of the lot according to the set of bonding parameters that were used to successfully strengthen the bond of the second package and not produce more than a threshold amount of variation in the strength of the bonds of the third packages. These remaining packages are presumably fit to be implemented in finished user devices that may be sold to customers. Nevertheless, the method 700 may include, at block 790, performing a final wire pull test on a subset of the remaining packages. For example, the wire pull test may be performed on one package from each strip of the lot. The wire pull test may be a non-destructive wire pull test such that the tested packages may still be implemented in finished user devices.

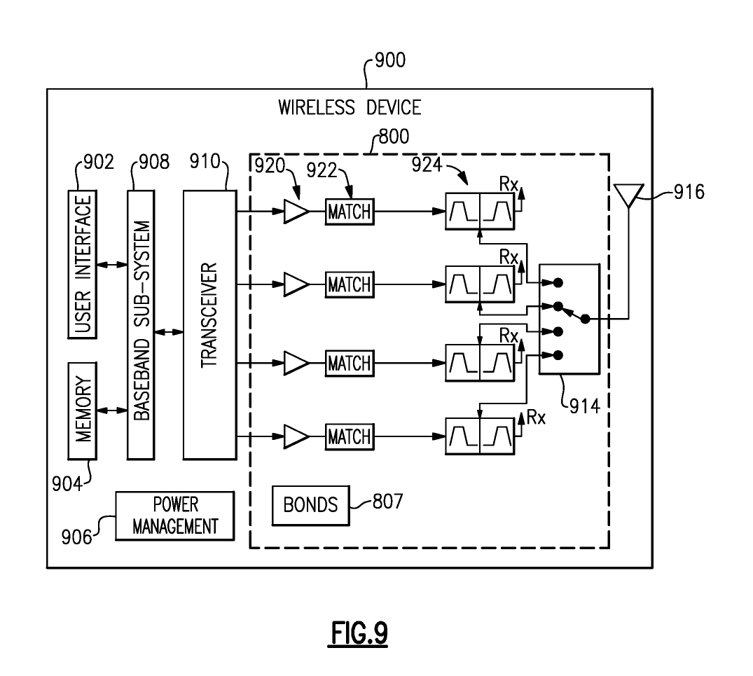

FIG. 8 shows that in some embodiments, some or all of the wire bonds described herein can be implemented, wholly or partially, in a module. Such a module can be, for example, a front-end module (FEM). In the example of FIG. 8, a module 800 can include a packaging substrate 802, and a number of components can be mounted on such a packaging substrate 802. The components can be mounted on the packaging substrate 802 by wire bonding the components to the packaging substrate 802 using one or more wire bonds 807. The wire bonds may be strengthened using the method 500 of FIG. 5 or any other method described herein. The components may include, for example, an FE-PMIC (Front-end Power Management Integrated Circuit) component 804, a power amplifier assembly 806, a match component 808, and a duplexer assembly 810 that can be mounted and/or implemented on and/or within the packaging substrate 802. Other components such as a number of SMT (surface-mount technology) devices 814 and an antenna switch module (ASM) 812 can also be mounted on the packaging substrate 802. Although all of the various components are depicted as being laid out on the packaging substrate 802, it will be understood that some component(s) can be implemented over other component(s).

In some implementations, a device and/or a circuit having one or more features described herein can be included in an RF electronic device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 9 depicts an example wireless device 900 having one or more advantageous features described herein. In the context of a module having one or more features as described herein, such a module can be generally depicted by a dashed box 800, and can be implemented as, for example, a front-end module (FEM). The module 800 includes a number of wire bonds 807 formed using one or more of the methods described above.

Referring to FIG. 9, power amplifiers (PAs) 920 can receive their respective RF signals from a transceiver 910 that can be configured and operated in known manners to generate RF signals to be amplified and transmitted, and to process received signals. The transceiver 910 is shown to interact with a baseband sub-system 908 that is configured to provide conversion between data and/or voice signals suitable for a user and RF signals suitable for the transceiver 910. The transceiver 910 can also be in communication with a power management component 906 that is configured to manage power for the operation of the wireless device 900. Such power management can also control operations of the baseband sub-system 908 and the module 800.

The baseband sub-system 908 is shown to be connected to a user interface 802 to facilitate various input and output of voice and/or data provided to and received from the user. The baseband sub-system 908 can also be connected to a memory 904 that is configured to store data and/or instructions to facilitate the operation of the wireless device, and/or to provide storage of information for the user.

In the example wireless device 900, outputs of the PAs 920 are shown to be matched (via respective match circuits 922) and routed to their respective duplexers 924. Such amplified and filtered signals can be routed to an antenna 916 through an antenna switch 914 for transmission. In some embodiments, the duplexers 924 can allow transmit and receive operations to be performed simultaneously using a common antenna (e.g., 916). In FIG. 9, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS (Global Positioning System).

As described herein, one or more features of the present disclosure can provide a number of advantages when implemented in systems such as those involving the wireless device of FIG. 9. For example, some materials that would normally be scrapped due to PCB quality, contamination, low pull test, etc. can be recovered. Further, strengthened wire bonds may be more reliable and durable than wire bonds formed without strengthening or by other methods. Thus, a manufacturer may increase yield and reduce costs by reducing the DPPM (defective parts per million) of the production.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method of strengthening a bond, the method comprising:
lowering an unthreaded capillary of a wire bonder to a bond strengthening site associated with a bond site of a formed wire bond;
applying a compressive force between the capillary and the bond strengthening site for a period of time;
applying at least one of heat or ultrasonic energy to the bond strengthening site for the period of time; and
raising the capillary from the bond strengthening site.

2. The method of claim 1 wherein the wire bond is a copper wire stitch bond.

3. The method of claim 1 wherein the bond site is disposed between the bond strengthening site and a wire of the wire bond.

4. The method of claim 1 wherein the bond site is between approximately 10 and 40 micrometers from the bond site.

5. The method of claim 1 wherein lowering the unthreaded capillary of the wire bonder includes retracting a wire of the wire bonder.

6. The method of claim 1 wherein applying at least one of heat or ultrasonic energy to the bond strengthening site includes heating the bond strengthening site to between approximately 100 and 300 degrees centigrade.

7. The method of claim 1 wherein applying at least one of heat or ultrasonic energy to the bond strengthening site includes applying approximately a 60 kilohertz (kHz) or 120 kHz ultrasonic acoustic wave.

8. The method of claim 1 further comprising receiving a set of bond strengthening parameters via a user interface, applying the compressive force and applying the at least one of heat or ultrasonic energy being performed according to the set of bond strengthening parameters.

9. A method of recovering at least a portion of a lot of packages, the method comprising:
forming a bond on each of a lot of packages;
performing a wire pull test of the bond of a first package of the lot of packages; and
responsive to determining that the wire pull test was failed, strengthening the bond of a second package of the lot of packages according to a set of bond strengthening parameters without introducing additional material to the bond of the second package.

10. The method of claim 9 wherein forming the bond on each of the lot of packages includes forming a copper wire stitch bond on each of the lot of packages.

11. The method of claim 9 wherein strengthening the bond of the second package includes applying a compressive force and at least one of heat or ultrasonic energy to the bond.

12. The method of claim 9 further comprising receiving the set of bond strengthening parameters via a user interface.

13. The method of claim 9 further comprising performing a wire pull test of the bond of a second package of the lot of packages.

14. The method of claim 13 further comprising, responsive to determining that the wire pull test of the bond of the second package was failed, strengthening the bond of another second package of the lot of packages according to a different set of bond strengthening parameters.

15. The method of claim 13 further comprising, responsive to determining that the wire pull test of the bond of the second package was passed, strengthening the bond of each of set of third packages of the lot of packages according the set of bond strengthening parameters.

16. The method of claim 15 further comprising determining whether a wire pull test of the bond of each of the set of third packages produced more than a threshold amount of variation.

17. The method of claim 16 further comprising, responsive to determining that the wire pull test of the bond of each of the set of third packages did not produce more than a threshold amount of variation, strengthening the bond of the remaining packages of the lot according to the set of bond strengthening parameters.

18. A wire bonding system comprising:
a wire bonder including a capillary; and
a processing module coupled to the wire bonder and configured to control the wire bonder to lower the capillary in an unthreaded state to a bond strengthening site associated with a bond site of a formed wire bond, apply a compressive force between the capillary and the bond strengthening site for a period of time, apply at least one of heat or ultrasonic energy to the bond strengthening site for the period of time, and raise the capillary from the bond strengthening site.

19. The wire bonding system of claim 18 further comprising a user interface configured to receive a set of bond strengthening parameters, the processing module being configured to control the wire bonder to apply the compressive force and apply the at least one of heat or ultrasonic energy according to the set of bond strengthening parameters.

20. The wire bonding system of claim 18 wherein the processing module is configured to control the wire bonder to retract a wire to place the capillary in the unthreaded state.
